(19) United States
(12) Patent Application Publication
(10) Pub. No.: US 2022/0085160 A1
(43) Pub. Date: Mar. 17, 2022

(54) SEMICONDUCTOR DEVICE AND METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Tatsuya NISHIWAKI, Komatsu Ishikawa (JP)

(21) Appl. No.: 17/470,561

(22) Filed: Sep. 9, 2021

(30) Foreign Application Priority Data
Sep. 14, 2020 (JP) 2020-153986

(51) Int. Cl. H01L 29/06; H01L 29/10; H01L 29/40; H01L 29/78; H01L 21/765; H01L 29/66

(52) U.S. Cl. CPC H01L 29/0661; H01L 29/1095; H01L 29/66734; H01L 29/7813; H01L 21/765; H01L 29/407

(57) ABSTRACT

A mesa part includes a first semiconductor region of, a second semiconductor region located on the first semiconductor region, a third semiconductor region located on the second semiconductor region, and a fourth semiconductor region located between a buried electrode part and the second semiconductor region. A gate electrode faces a side surface of the second semiconductor region forming a portion of a first sidewall of the mesa part. An upper electrode includes a major portion and a contact portion. The major portion is located on a semiconductor structure part. The contact portion extends from the major portion into the buried electrode part and reaches a second sidewall of the mesa part. The second sidewall is at a side opposite to the first sidewall. The contact portion contacts the second and fourth semiconductor regions.

### CROSS-REFERENCE TO RELATED APPLICATION

This application is based upon and claims the benefit of priority from Japanese Patent Application No. 2020-153986, filed on Sep. 14, 2020; the entire contents of which are incorporated herein by reference.

### FIELD

Embodiments described herein relate generally to a semiconductor device and a method for manufacturing a semiconductor device.

### BACKGROUND

In a semiconductor device that has a trench gate structure, the on-resistance can be reduced by pitch shrinking by reducing the width of a mesa part between adjacent trenches. When forming a trench contact at the central portion of such a fine mesa part, fluctuation of the distance between the channel and the p⁺-layer at the trench contact bottom portion may occur due to misalignment of the lithography; and problems such as fluctuation of the threshold voltage and/or the on-resistance may occur.

### BRIEF DESCRIPTION OF THE DRAWINGS

FIG. 1 is a schematic cross-sectional view of a semiconductor device of a first embodiment;

FIG. 2 is an A-A′ cross-sectional view of FIG. 1;

FIG. 3A to FIG. 8B are schematic cross-sectional views showing a method for manufacturing the semiconductor device of the first embodiment;

FIG. 9 is a schematic cross-sectional view of a semiconductor device of a second embodiment;

FIG. 10 is a B-B′ cross-sectional view of FIG. 9;

FIG. 11A and FIG. 11B are schematic cross-sectional views showing a method for manufacturing the semiconductor device of the second embodiment;

FIG. 12 is a schematic cross-sectional view of a semiconductor device of a third embodiment;

FIG. 13 is a C-C′ cross-sectional view of FIG. 12;

FIG. 14A to FIG. 17B are schematic cross-sectional views showing a method for manufacturing the semiconductor device of the third embodiment;

FIG. 18 is a schematic cross-sectional view of a semiconductor device of a fourth embodiment;

FIG. 19 is a D-D′ cross-sectional view of FIG. 18.

### DETAILED DESCRIPTION

According to one embodiment, a semiconductor device includes a semiconductor structure part. The semiconductor structure part includes a plurality of buried electrode parts, and a mesa part located between the plurality of buried electrode parts. The mesa part is next to the buried electrode part. The mesa part includes a first semiconductor region of a first conductivity type, a second semiconductor region located on the first semiconductor region, the second semiconductor region being of a second conductivity type, a third semiconductor region located on the second semiconductor region, the third semiconductor region being of the first conductivity type, and a fourth semiconductor region located between the buried electrode part and the second semiconductor region, the fourth semiconductor region being of the second conductivity type and having a higher second-conductivity-type impurity concentration than the second semiconductor region. The semiconductor device includes a gate electrode located in the buried electrode part, the gate electrode facing a side surface of the second semiconductor region forming a portion of a first sidewall of the mesa part. The semiconductor device includes a gate insulating film located between the gate electrode and the side surface of the second semiconductor region. And the semiconductor device includes an upper electrode including a major portion and a contact portion. The major portion is located on the semiconductor structure part. The contact portion extends from the major portion into the buried electrode part and reaches a second sidewall of the mesa part. The second sidewall is at a side opposite to the first sidewall. The contact portion contacts the second and fourth semiconductor regions.

Embodiments will now be described with reference to the drawings. The same components in the drawings are marked with the same reference numerals.

Although the first conductivity type is described as an n-type and the second conductivity type is described as a p-type in embodiments described below, the first conductivity type may be the p-type, and the second conductivity type may be the n-type.

### First Embodiment

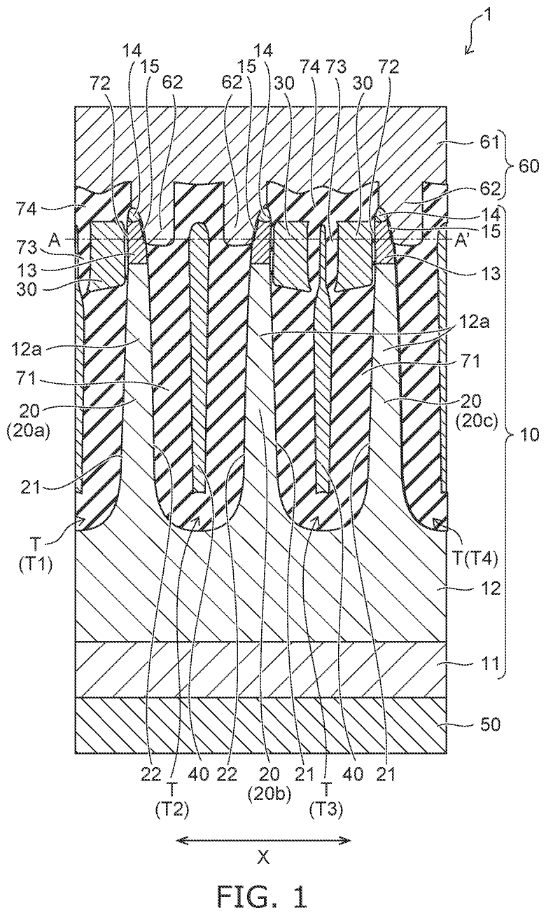

FIG. 1 is a schematic cross-sectional view of a semiconductor device 1 of a first embodiment.

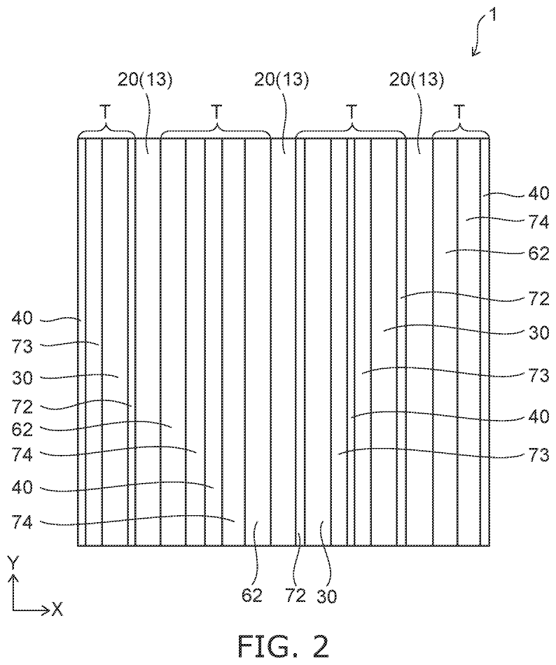

FIG. 2 is an A-A′ cross-sectional view of FIG. 1.

The semiconductor device 1 includes a semiconductor structure part 10, an upper electrode 60, a lower electrode 50, a gate electrode 30, and a field plate electrode 40. The upper electrode 60 is located at the upper surface of the semiconductor structure part 10; and the lower electrode 50 is located at the lower surface of the semiconductor structure part 10. For example, the upper electrode 60 is a source electrode; and the lower electrode 50 is a drain electrode. The semiconductor device 1 is a vertical semiconductor device in which a current is caused to flow in a direction (the vertical direction) connecting the lower electrode 50 and the upper electrode 60 by a control of the gate electrode 30.

The materials of the substrate, the semiconductor layers, and the semiconductor regions that are included in the semiconductor structure part 10 are, for example, silicon. Or, the materials of the substrate, the semiconductor layers, and the semiconductor regions that are included in the semiconductor structure part 10 may be, for example, silicon carbide, gallium nitride, etc.

The semiconductor structure part 10 includes an n⁺-type drain layer (or substrate) 11 that is located on the lower electrode 50, and an n-type drift layer 12 that is located on the drain layer 11. The n-type impurity concentration of the drift layer 12 is less than the n-type impurity concentration of the drain layer 11. The drain layer 11 is electrically connected with the lower electrode 50. The semiconductor structure part 10 also includes multiple buried electrode parts T, and a mesa part 20 that is located between adjacent buried electrode parts T and is next to the buried electrode parts T.

In FIG. 2, two orthogonal directions in a plane parallel to the upper surface or lower surface of the semiconductor structure part 10 are taken as an X-direction and a Y-direction. The multiple buried electrode parts T are separated from each other in the X-direction and extend in stripe shapes in the Y-direction. The multiple mesa parts 20 are separated from each other in the X-direction and extend in stripe shapes in the Y-direction.

In FIG. 1, any four buried electrode parts T are illustrated as a first buried electrode part T1, a second buried electrode part T2, a third buried electrode part T3, and a fourth buried electrode part T4. Also, in FIG. 1, any three mesa parts 20 are illustrated as a first mesa part 20a, a second mesa part 20b, and a third mesa part 20c. In the following description, the first buried electrode part T1, the second buried electrode part T2, the third buried electrode part T3, and the fourth buried electrode part T4 may be referred to as simply the buried electrode part T without differentiation; and the first mesa part 20a, the second mesa part 20b, and the third mesa part 20c may be referred to as simply the mesa part 20 without differentiation.

The first mesa part 20a is located between the first buried electrode part T1 and the second buried electrode part T2 and is next to the first buried electrode part T1 and the second buried electrode part T2. The second mesa part 20b is located between the second buried electrode part T2 and the third buried electrode part T3 and is next to the second buried electrode part T2 and the third buried electrode part T3. The third mesa part 20c is located between the third buried electrode part T3 and the fourth buried electrode part T4 and is next to the third buried electrode part T3 and the fourth buried electrode part T4.

The buried electrode part T that includes the gate electrode 30 and the field plate electrode 40 and the buried electrode part T that includes the field plate electrode 40 but does not include the gate electrode 30 are alternately repeated in the X-direction. In the example shown in FIG. 1, the first buried electrode part T1 and the third buried electrode part T3 include the gate electrode 30 and the field plate electrode 40. The second buried electrode part T2 and the fourth buried electrode part T4 include the field plate electrode 40 but do not include the gate electrode 30.

The buried electrode part T that does not include the gate electrode 30 includes a contact portion 62 that is a portion of the upper electrode 60. In the example shown in FIG. 1, the second buried electrode part T2 and the fourth buried electrode part T4 include the contact portion 62 and the field plate electrode 40.

The mesa part 20 that extends in the Y-direction includes two sidewalls. The sidewall of the mesa part 20 that the gate electrode 30 faces is taken as a first sidewall 21. The mesa part 20 includes a second sidewall 22 at the side opposite to the first sidewall 21. The contact portion 62 contacts the second sidewall 22.

The mesa part 20 includes an n-type drift region (a first semiconductor region) 12a that is a portion of the drift layer 12, a p-type base region (a second semiconductor region) 13 that is located on the drift region 12a, an n⁺-type source region (a third semiconductor region) 14 that is located on the base region 13, and a p⁺-type base contact region (a fourth semiconductor region) 15 that is located between the base region 13 and the buried electrode part T.

The n-type impurity concentration of the source region 14 is greater than the n-type impurity concentration of the drift region 12a. The p-type impurity concentration of the base contact region 15 is greater than the p-type impurity concentration of the base region 13.

The base contact region 15 is formed in a portion of the base region 13. The side surface of the base contact region 15 forms a portion of the second sidewall 22 of the mesa part 20.

The drift region 12a is formed in the entire width direction of the mesa part 20 (the X-direction), includes a side surface that forms a portion of the first sidewall 21 of the mesa part 20, and includes a side surface that forms a portion of the second sidewall 22. The base region 13 is formed in the entire width direction of the mesa part 20 (the X-direction), includes a side surface that forms a portion of the first sidewall 21 of the mesa part 20, and includes a side surface that forms a portion of the second sidewall 22. The source region 14 is formed in the entire width direction of the mesa part 20 (the X-direction), includes a side surface that forms a portion of the first sidewall 21 of the mesa part 20, and includes a side surface that forms a portion of the second sidewall 22. The upper surface of the source region 14 forms the upper surface of the mesa part 20.

The bottom of the buried electrode part T is positioned in the drift layer 12 and does not reach the drain layer 11.

The buried electrode part T (e.g., the third buried electrode part T3 in FIG. 1) that includes the gate electrodes 30 includes the gate electrode 30 that faces the side surface of the base region 13 forming a portion of the first sidewall 21 of the second mesa part 20b and the gate electrode 30 that faces the side surface of the base region 13 forming a portion of the first sidewall 21 of the third mesa part 20c. A gate insulating film 72 is located between the gate electrode 30 and the side surfaces of the base region 13.

The field plate electrode 40 is positioned at substantially the width-direction (X-direction) center of each buried electrode part T. An insulating film 71 is located between the field plate electrode 40 and the drift layer 12; and the field plate electrode 40 does not contact the drift layer 12. An insulating film 73 is located between the field plate electrode 40 and the gate electrode 30.

The upper electrode 60 includes a major portion 61 that spreads in a planar shape on the semiconductor structure part 10, and the contact portion 62 that extends from the major portion 61 into the buried electrode part T (in the example shown in FIG. 1, the second buried electrode part T2 and the fourth buried electrode part T4) to reach the second sidewall 22 of the mesa part 20. For example, the major portion 61 and the contact portion 62 are formed to have a continuous body of a metal material.

The contact portion 62 is in contact with and electrically connected to the source region 14 and the base contact region 15 of the mesa part 20.

An insulating film 74 is located between the gate electrode 30 and the upper electrode 60 and between the field plate electrode 40 and the upper electrode 60.

The gate electrode 30 faces one sidewall (the first sidewall 21) of the mesa part 20 via the gate insulating film 72. The contact portion 62 contacts the source region 14 and the base contact region 15 at the other sidewall (the second sidewall 22) of the mesa part 20.

An n-type channel (an inversion layer) can be formed in the portion of the base region 13 that faces the gate electrode 30 by applying a voltage that is not less than a threshold to the gate electrode 30.

The field plate electrode 40 extends through the buried electrode part T below the gate electrode 30 and the contact portion 62. Compared to the bottom portion of the gate electrode 30, the bottom portion of the field plate electrode 40 is more proximate to the drain layer 11.

For example, the field plate electrode 40 is electrically connected with the upper electrode 60. Or, the field plate electrode 40 may be electrically connected with the gate electrode 30. The field plate electrode 40 relaxes the distribution of the electric field of the drift layer 12 in the off-state in which the application of the voltage that is not less than the threshold to the gate electrode 30 is stopped.

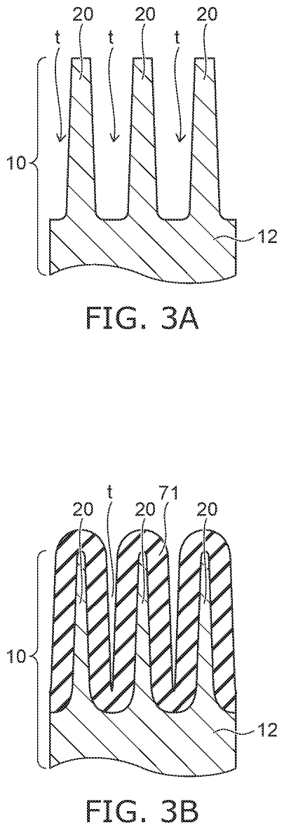

A method for manufacturing the semiconductor device 1 of the first embodiment will now be described with reference to FIGS. 3A to 8B.

As shown in FIG. 3A, multiple trenches t and multiple mesa parts 20 are formed in the drift layer 12. For example, the trenches t are formed by RIE (Reactive Ion Etching). The mesa parts 20 that are portions of the drift layer 12 are formed between the adjacent trenches t simultaneously with forming the multiple trenches t.

After forming the trench t and the mesa part 20, the insulating film 71 is formed to cover the inner wall of the trench t and the mesa part 20 as shown in FIG. 3B. The insulating film 71 is, for example, a silicon oxide film that is formed by thermal oxidation. The thermal oxidation reaction causes the width of the mesa part 20 to be narrower than before thermal oxidation. Or, the insulating film 71 may be formed by CVD (Chemical Vapor Deposition).

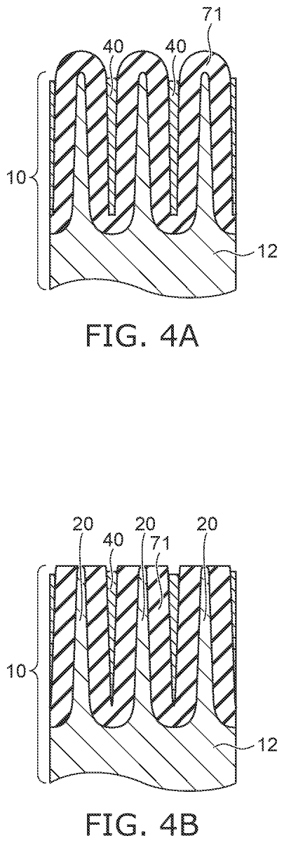

A gap remains at the inner side of the insulating film 71 in the trench t. As shown in FIG. 4A, the field plate electrode 40 is filled into the gap. For example, the material of the field plate electrode 40 is deposited on the insulating film 71 by CVD; subsequently, the upper surface of the material is caused to recede to the position shown in FIG. 4A.

The upper surface of the insulating film 71 that covers the mesa parts 20 is planarized, and the upper surfaces of the mesa parts 20 are exposed from under the insulating film 71 as shown in FIG. 4B.

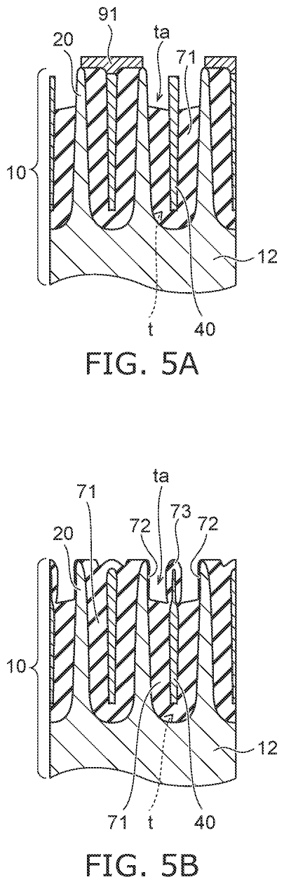

As shown in FIG. 5A, among two adjacent trenches t, the insulating film 71 of one trench t is covered with a mask 91; and the insulating film 71 of the other trench t is etched. The upper surface of the etched insulating film 71 is caused to recede to the position shown in FIG. 5A; and a recess ta for filling the gate electrode is formed in the upper portion of the other trench t.

One sidewall of the upper portion of the mesa part 20 is exposed in the recess ta. The upper portion of the field plate electrode 40 also is exposed in the recess ta.

As shown in FIG. 5B, the gate insulating film (the silicon oxide film) 72 is formed at the one sidewall of the mesa part 20 that is exposed in the recess ta by, for example, thermal oxidation of the exposed portion of the mesa part 20. At this time, a thermal oxidation reaction also progresses from the insulating film (the silicon oxide film) 71 that is located in the trench t next to the other sidewall of the mesa part 20. The thermal oxidation reaction from the insulating film 71 causes the sidewall of the upper portion of the mesa part 20 at the side opposite to the sidewall at which the gate insulating film 72 is formed to slightly tilt to be bent or curved toward the recess ta side.

Thermal oxidation of the exposed upper portion of the field plate electrode 40 also occurs, and the insulating film (the silicon oxide film) 73 is formed between the recess ta and the field plate electrode 40.

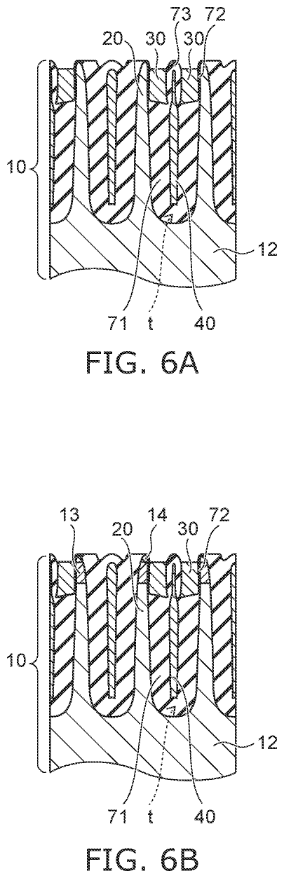

As shown in FIG. 6A, the gate electrode 30 is filled into the recess ta. The gate electrode 30 faces the sidewall of the mesa part 20 via the gate insulating film 72.

After forming the gate electrode 30, a p-type impurity and an n-type impurity are implanted in this order into the mesa part 20 by, for example, ion implantation. As shown in FIG. 6B, by performing thermal diffusion processing after the implantation, the p-type base region 13 is formed in the portion of the mesa part 20 that faces the gate electrode 30; and the n-type source region 14 is formed on the base region 13.

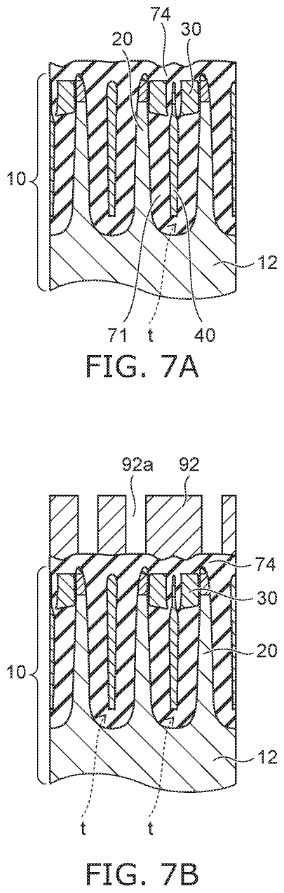

After forming the base region 13 and the source region 14, the insulating film 74 that covers the mesa part 20 and the gate electrode 30 is formed as shown in FIG. 7A.

As shown in FIG. 7B, a mask 92 is formed on the upper surface of the insulating film 74. An opening 92a is formed in the mask 92 by lithography. The opening 92a is positioned between the mesa part 20 and the field plate electrode 40 above the trench t into which the gate electrode 30 is not filled.

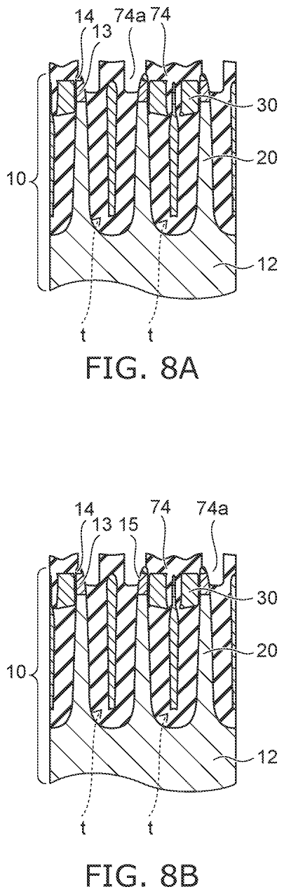

Then, the insulating film 74 is etched by, for example, RIE using the mask 92. Thereby, as shown in FIG. 8A, a contact trench 74a is formed in the insulating film 74. The contact trench 74a reaches the second sidewall at the upper portion of the mesa part 20 at the side opposite to the first sidewall that the gate electrode 30 faces.

The side surface of the source region 14 and the side surface of the base region 13 are exposed in the contact trench 74a. As shown in FIG. 8B, the p-type base contact region 15 that has a higher p-type impurity concentration than the base region 13 is formed in the side surface of the base region 13 exposed in the contact trench 74a by, for example, implanting a p-type impurity by ion implantation into the exposed side surface of the base region 13 and by subsequently performing thermal diffusion processing.

After forming the base contact region 15, the contact portion 62 of the upper electrode 60 is filled into the contact trench 74a as shown in FIG. 1. The contact portion 62 contacts the source region 14 and the base contact region 15 that form a portion of the second sidewall 22 of the mesa part 20 at the side opposite to the first sidewall 21 that the gate electrode 30 faces.

In other words, the upper portion of the first sidewall 21 of the mesa part 20 faces the gate electrode 30 located in the buried electrode part T that is next to the first sidewall 21; the contact portion 62 is located in the buried electrode part T that is next to the second sidewall 22 at the side opposite to the first sidewall 21; and the contact portion 62 contacts the second sidewall 22.

According to embodiments described above, a recess is not formed in the mesa part 20 by etching to form the contact trench 74a for connecting the upper electrode 60 to the source region 14 and the base contact region 15. According to the embodiment as shown in FIG. 8A, the contact trench 74a that reaches the sidewall of the upper portion of the mesa part 20 is formed by etching the insulating film 74 that covers the mesa part 20.

The insulating film 74 and the mesa part 20 are of mutually-different materials; for example, the insulating film 74 is a silicon oxide film; and the mesa part 20 is a silicon portion. Therefore, the mesa part 20 functions as an etching stopper when etching the insulating film 74; and the contact trench 74a is formed self-aligningly with respect to the sidewall of the mesa part 20. Therefore, the fluctuation with respect to the gate electrode 30 can be suppressed for the position of the base contact region 15 formed by implanting the p-type impurity into the side surface of the base region 13 exposed in the contact trench 74a. Thereby, the distance between the channel that is formed in the first sidewall 21 of the mesa part 20 and the base contact region 15 that is formed in the second sidewall 22 at the side opposite to the first sidewall 21 can be constant, and the fluctuation of the threshold voltage and/or the on-resistance can be suppressed.

The side surface of the base region 13 of the mesa part 20 that is reached by the contact trench 74a (that is contacted by the contact portion 62) is oblique to the side surface of the drift region 12a under the base region 13 in the thermal oxidation shown in FIG. 5B described above. Accordingly, the side surface of the base region 13 that is oblique or curved with respect to the direction of the ion implantation (the vertical direction along the depth direction of the trench t) can be exposed in the contact trench 74a; and the formation of the base contact region 15 by ion implantation via the contact trench 74a is easier.

The width of the mesa part 20 can be reduced because it is unnecessary to form a recess in the mesa part 20 for forming the contact portion. A tensile stress that is caused by the insulating film 71 can be applied to the fine mesa part 20; the carrier mobility in the drift region 12a can be increased; and the on-resistance can be reduced.

Compared to a configuration in which channels are formed in both sidewalls of the mesa part 20, the channel density is lower according to the embodiment in which the channel is formed in only one sidewall of the mesa part 20; however, the reduction of the channel density can be compensated by pitch shrinking and by reducing the width of the mesa part 20. The structure according to the embodiment is particularly effective in a high breakdown voltage element (of not less than one hundred volts) in which the fraction of the channel resistance is small.

### Second Embodiment

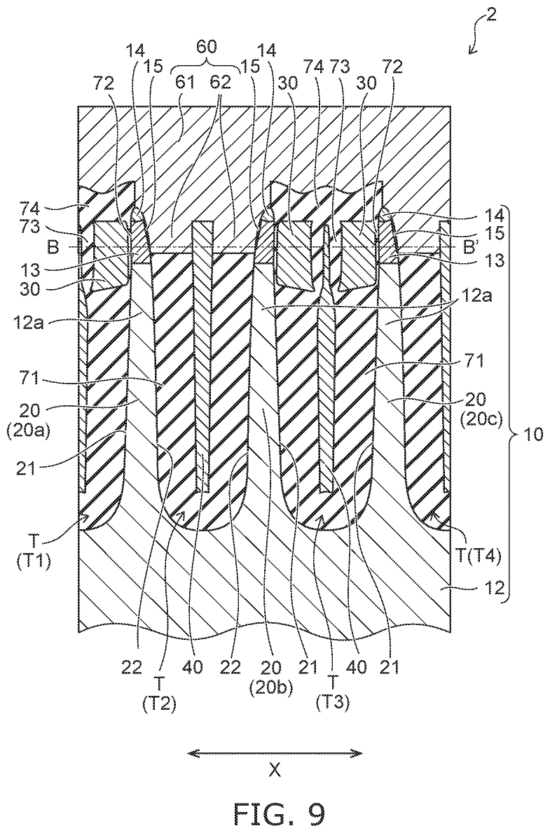

FIG. 9 is a schematic cross-sectional view of a semiconductor device 2 of a second embodiment.

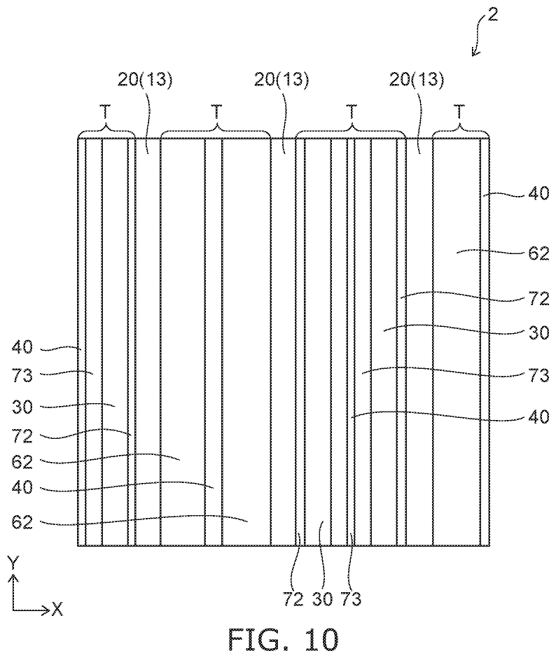

FIG. 10 is a B-B′ cross-sectional view of FIG. 9.

The second embodiment differs from the first embodiment for the following aspects.

For the two mesa parts 20 (the first mesa part 20a and the second mesa part 20b) that are next to the buried electrode part T (e.g., the second buried electrode part T2 in FIG. 9) in which the contact portion 62 is located, the contact portion 62 that contacts the second sidewall 22 of the first mesa part 20a and the contact portion 62 that contacts the second sidewall 22 of the second mesa part 20b are linked to each other in the second buried electrode part T2.

The field plate electrode 40 that is located in the second buried electrode part T2 also contacts the contact portions 62 that are linked to each other in the second buried electrode part T2.

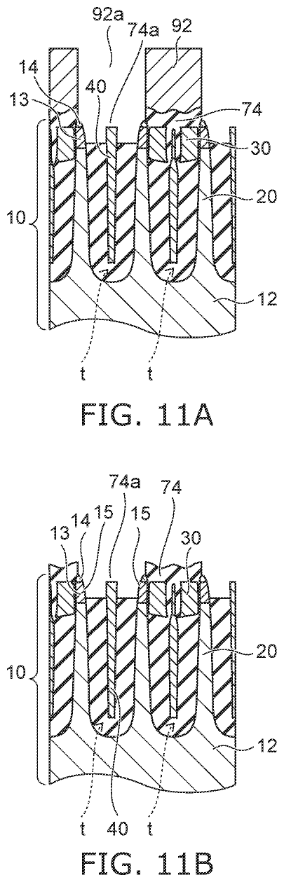

A method for manufacturing the semiconductor device 2 of the second embodiment will now be described with reference to FIGS. 11A and 11B.

The processes up to FIGS. 3A to 7A proceed similarly to those of the first embodiment. Subsequently, according to the second embodiment as shown in FIG. 11A, the width of the opening 92a of the mask 92 that is formed on the insulating film 74 is set to be greater than that of the first embodiment. The opening 92a is positioned above the trench t in which the gate electrode 30 is not provided; and the upper surface of the insulating film 74 on the trench t is exposed in the opening 92a.

By etching the insulating film 74 in this state, the contact trench 74a that exposes the upper portions of the sidewalls of the two mesa parts 20 below the opening 92a and the upper portion of the field plate electrode 40 located between the two mesa parts 20 is formed.

Subsequently, similarly to the first embodiment, the base contact region 15 is formed in the side surface of the base region 13 that is exposed in the contact trench 74a as shown in FIG. 11B by ion implantation via the contact trench 74a. Subsequently, the trench contact portion 62 is formed in the contact trench 74a.

According to the second embodiment, compared to the first embodiment, the lithography is easier because the width of the opening 92a of the mask 92 for forming the contact trench 74a can be increased.

### Third Embodiment

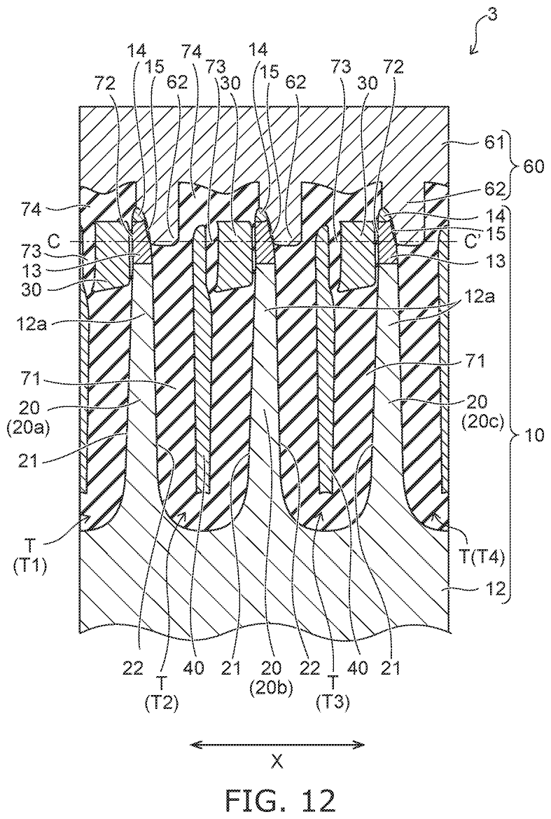

FIG. 12 is a schematic cross-sectional view of a semiconductor device 3 of a third embodiment.

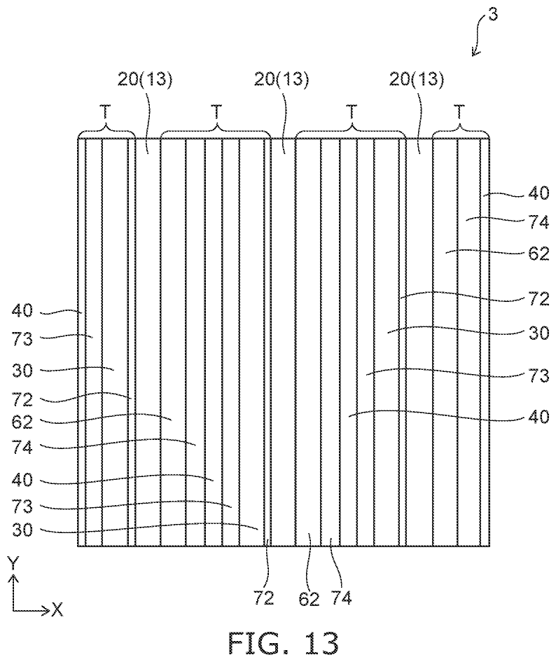

FIG. 13 is a C-C′ cross-sectional view of FIG. 12.

According to the third embodiment, both the gate electrode 30 and the contact portion 62 are located in one buried electrode part T. In the example shown in FIG. 12, the contact portion 62 that is located in the second buried electrode part T2 contacts the source region 14 and the base contact region 15 at the upper portion of the second sidewall 22 of the first mesa part 20a. The gate electrode 30 that is located in the second buried electrode part T2 faces, via the gate insulating film 72, the base region 13 that forms a portion of the first sidewall 21 of the second mesa part 20b. The contact portion 62 that is located in the third buried electrode part T3 contacts the source region 14 and the base contact region 15 at the upper portion of the second sidewall 22 of the second mesa part 20b. The gate electrode 30 that is located in the third buried electrode part T3 faces, via the gate insulating film 72, the base region 13 that forms a portion of the first sidewall 21 of the third mesa part 20c.

The field plate electrode 40 is positioned between the gate electrode 30 and the contact portion 62 in one buried electrode part T.

The mesa part 20 and the buried electrode part T in which the gate electrode 30, the contact portion 62, and the field plate electrode 40 are located are alternately and repeatedly arranged in the X-direction.

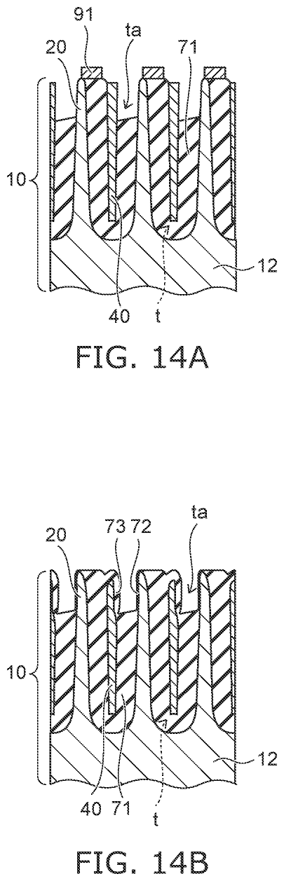

A method for manufacturing the semiconductor device 3 of the third embodiment will now be described with reference to FIGS. 14A to 17B.

The processes up to FIGS. 3A to 4B proceed similarly to those of the first embodiment. Subsequently, according to the third embodiment as shown in FIG. 14A, the upper surface of one insulating film 71 of the insulating films 71 located at the two sides of the field plate electrode 40 filled into the trench t is covered with the mask 91; and the other insulating film 71 that is not covered with the mask 91 is etched. The recess ta for filling the gate electrode into the insulating film 71 is formed by causing the upper surface of the etched insulating film 71 to recede to the position shown in FIG. 14A.

One sidewall of the upper portion of the mesa part 20 and one sidewall of the upper portion of the field plate electrode 40 are exposed in the recess ta.

As shown in FIG. 14B, the gate insulating film (the silicon oxide film) 72 is formed at the one sidewall of the mesa part 20 that is exposed in the recess ta by, for example, thermal oxidation of the exposed portion of the mesa part 20. At this time, a thermal oxidation reaction also progresses from the insulating film (the silicon oxide film) 71 that is located in the trench t next to the other sidewall of the mesa part 20. The thermal oxidation reaction from the insulating film 71 causes the sidewall at the side opposite to the sidewall of the upper portion of the mesa part 20 at which the gate insulating film 72 is formed to slightly tilt to be bent or curved toward the recess ta side.

Thermal oxidation of the exposed portion of the field plate electrode 40 also occurs, and the insulating film (the silicon oxide film) 73 is formed between the recess ta and the field plate electrode 40.

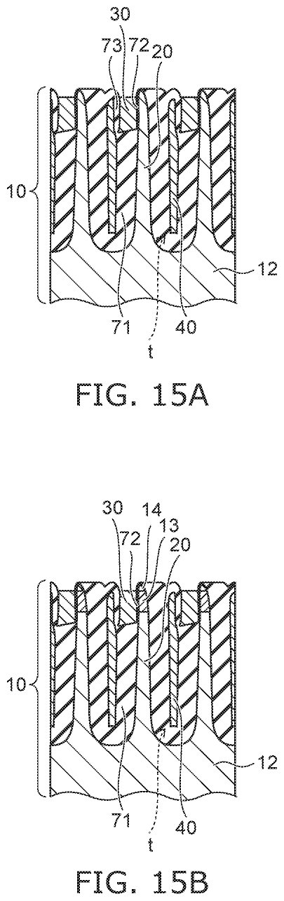

As shown in FIG. 15A, the gate electrode 30 is filled into the recess ta. The gate electrode 30 faces the sidewall of the mesa part 20 via the gate insulating film 72.

After forming the gate electrode 30, a p-type impurity and an n-type impurity are implanted in this order into the mesa part 20 by, for example, ion implantation. As shown in FIG. 15B, by performing thermal diffusion processing after the implantation, the p-type base region 13 is formed in the portion of the mesa part 20 that faces the gate electrode 30; and the n-type source region 14 is formed on the base region 13.

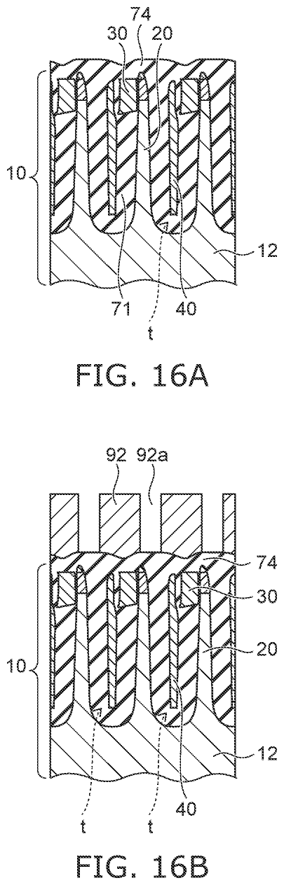

After forming the base region 13 and the source region 14, the insulating film 74 that covers the mesa part 20 and the gate electrode 30 is formed as shown in FIG. 16A.

As shown in FIG. 16B, the mask 92 is formed on the upper surface of the insulating film 74. The opening 92a is formed in the mask 92 by lithography. The opening 92a is positioned between the mesa part 20 and the field plate electrode 40 above the portion into which the gate electrode 30 is not filled.

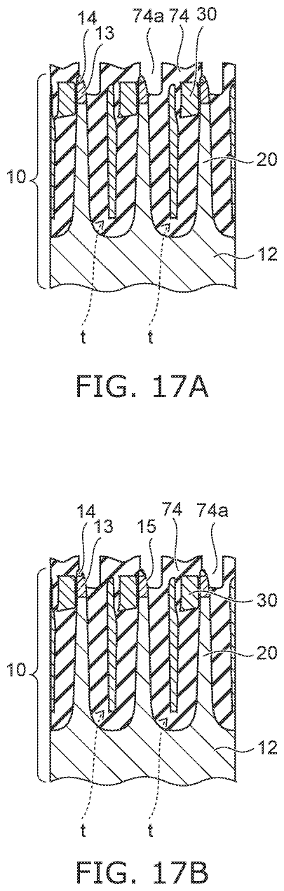

Then, the insulating film 74 is etched by, for example, RIE using the mask 92. Thereby, as shown in FIG. 17A, the contact trench 74a is formed in the insulating film 74. The contact trench 74a reaches the second sidewall at the upper portion of the mesa part 20 at the side opposite to the first sidewall that the gate electrode 30 faces.

The side surface of the source region 14 and the side surface of the base region 13 are exposed in the contact trench 74a. As shown in FIG. 17B, the p-type base contact region 15 that has a higher p-type impurity concentration than the base region 13 is formed in the side surface of the base region 13 exposed in the contact trench 74a by, for example, implanting a p-type impurity by ion implantation into the exposed side surface of the base region 13 and by subsequently performing thermal diffusion processing.

After forming the base contact region 15, the contact portion 62 of the upper electrode 60 is filled into the contact trench 74a as shown in FIG. 12. The contact portion 62 contacts the source region 14 and the base contact region 15 that form a portion of the second sidewall 22 of the mesa part 20 at the side opposite to the first sidewall 21 that the gate electrode 30 faces.

According to the third embodiment as well, the contact trench 74a that reaches the sidewall of the upper portion of the mesa part 20 is formed by etching the insulating film 74 that covers the mesa part 20. The mesa part 20 functions as an etching stopper when etching the insulating film 74; and the contact trench 74a is formed self-aligningly with respect to the sidewall of the mesa part 20. Therefore, the fluctuation with respect to the gate electrode 30 can be suppressed for the position of the base contact region 15 formed by implanting the p-type impurity into the side surface of the base region 13 exposed in the contact trench 74a. Thereby, the distance between the channel that is formed in the first sidewall 21 of the mesa part 20 and the base contact region 15 that is formed in the second sidewall 22 at the side opposite to the first sidewall 21 can be constant, and the fluctuation of the threshold voltage and/or the on-resistance can be suppressed.

According to the third embodiment, the layout is easy because the buried electrode parts T that have the same structure and the mesa parts 20 that have the same structure are alternately located in the X-direction that crosses (e.g., is orthogonal to) the Y-direction in which the buried electrode part T and the mesa part 20 extend.

### Fourth Embodiment

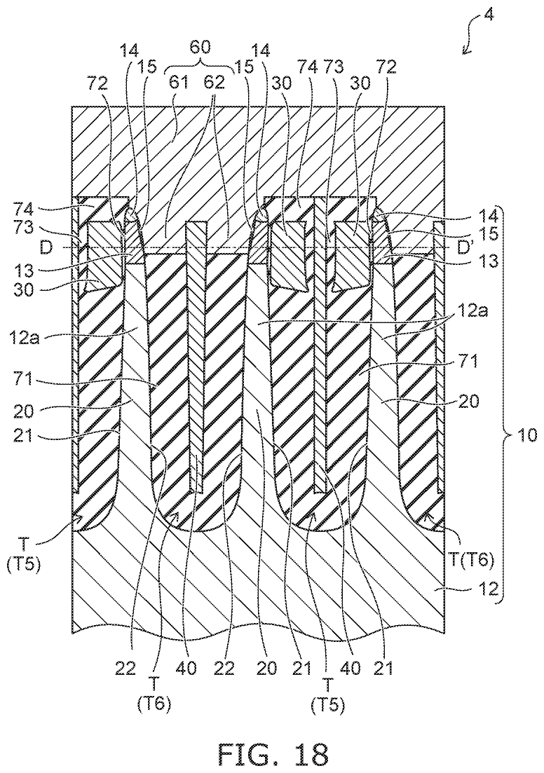

FIG. 18 is a schematic cross-sectional view of a semiconductor device 4 of a fourth embodiment.

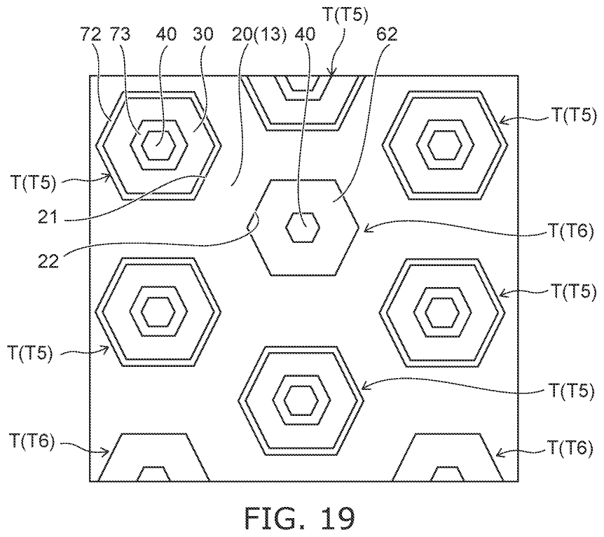

FIG. 19 is a D-D′ cross-sectional view of FIG. 18.

According to the fourth embodiment, the multiple buried electrode parts T are formed in the drift layer 12 in columnar shapes instead of stripe shapes. Although a hexagonal-prism buried electrode part T is shown as an example in FIG. 19, the buried electrode part T may be a prism other than a circular column or a hexagonal prism.

The multiple buried electrode parts T include a buried electrode part T5 that includes the field plate electrode 40 and the gate electrode 30 but does not include the contact portion 62, and a buried electrode part T6 that includes the field plate electrode 40 and the contact portion 62 but does not include the gate electrode 30.

The field plate electrode 40 is positioned at the central axis of each of the buried electrode parts T5 and T6. The gate electrode 30 surrounds the periphery of the upper portion of the field plate electrode 40 of the buried electrode part T5 with the insulating film 73 interposed. The contact portion 62 surrounds the periphery of the upper portion of the field plate electrode 40 of the buried electrode part T6. The upper portion of the field plate electrode 40 of the buried electrode part T6 contacts the contact portion 62. The field plate electrode 40 of the buried electrode part T5 extends through the insulating film 74 between the buried electrode part T5 and the upper electrode 60 and is connected with the major portion 61 of the upper electrode 60.

According to the fourth embodiment as well, similarly to embodiments described above, the contact trench that reaches the sidewall of the upper portion of the mesa part 20 can be formed by etching the insulating film 74 that covers the mesa part 20. Therefore, the fluctuation with respect to the gate electrode 30 can be suppressed for the position of the base contact region 15 formed by implanting the p-type impurity into the side surface of the base region 13 exposed in the contact trench. Thereby, the distance between the channel that is formed in the first sidewall 21 of the mesa part 20 and the base contact region 15 that is formed in the second sidewall 22 at the side opposite to the first sidewall 21 can be constant, and the fluctuation of the threshold voltage and/or the on-resistance can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a semiconductor structure part,
the semiconductor structure part including
a plurality of buried electrode parts, and
a mesa part located between the plurality of buried electrode parts,
the mesa part being next to the buried electrode part,
the mesa part including
a first semiconductor region of a first conductivity type,
a second semiconductor region located on the first semiconductor region, the second semiconductor region being of a second conductivity type,
a third semiconductor region located on the second semiconductor region, the third semiconductor region being of the first conductivity type, and
a fourth semiconductor region located between the buried electrode part and the second semiconductor region, the fourth semiconductor region being of the second conductivity type and having a higher second-conductivity-type impurity concentration than the second semiconductor region;
a gate electrode located in the buried electrode part, the gate electrode facing a side surface of the second semiconductor region forming a portion of a first sidewall of the mesa part;
a gate insulating film located between the gate electrode and the side surface of the second semiconductor region; and
an upper electrode including a major portion and a contact portion,
the major portion being located on the semiconductor structure part,
the contact portion extending from the major portion into the buried electrode part and reaching a second sidewall of the mesa part,
the second sidewall being at a side opposite to the first sidewall,
the contact portion contacting the second and fourth semiconductor regions.

2. The device according to claim 1, wherein
at least four of the buried electrode parts are provided,
the at least four of the buried electrode parts include a first buried electrode part, a second buried electrode part, a third buried electrode part, and a fourth buried electrode part,
at least three of the mesa parts are provided,
the at least three of the mesa parts include a first mesa part, a second mesa part, and a third mesa part,
the first mesa part is located between the first buried electrode part and the second buried electrode part and is next to the first buried electrode part and the second buried electrode part,
the second mesa part is located between the second buried electrode part and the third buried electrode part and is next to the second buried electrode part and the third buried electrode part,
the third mesa part is located between the third buried electrode part and the fourth buried electrode part and is next to the third buried electrode part and the fourth buried electrode part,
the gate electrode that faces a first sidewall of the first mesa part is located in the first buried electrode part,
the contact portion that contacts a second sidewall of the first mesa part is located in the second buried electrode part,
the contact portion that contacts a second sidewall of the second mesa part is located in the second buried electrode part,
the gate electrode that faces a first sidewall of the second mesa part is located in the third buried electrode part,
the gate electrode that faces a first sidewall of the third mesa part is located in the third buried electrode part, and
the contact portion that contacts a second sidewall of the third mesa part is located in the fourth buried electrode part.

3. The device according to claim 2, wherein
the second buried electrode part and the fourth buried electrode part do not include the gate electrode.

4. The device according to claim 2, wherein
the contact portion that contacts the second sidewall of the first mesa part and the contact portion that contacts the second sidewall of the second mesa part are linked to each other by the second buried electrode part.

5. The device according to claim 4, further comprising:
a field plate electrode located in the second buried electrode part,
the field plate electrode contacting the contact portion.

6. The device according to claim 5, wherein
the second buried electrode part does not include the gate electrode.

7. The device according to claim 1, wherein
both the gate electrode and the contact portion are located in one of the buried electrode parts.

8. The device according to claim 7, wherein
the buried electrode part further includes a field plate electrode positioned between the gate electrode and the contact portion.

9. The device according to claim 1, wherein
the buried electrode part and the mesa part extend in stripe shapes.

10. The device according to claim 1, wherein
the plurality of buried electrode parts is formed in columnar shapes.

11. The device according to claim 10, wherein
the plurality of buried electrode parts includes:
a fifth buried electrode part including the gate electrode and not including the contact portion; and
a sixth buried electrode part including the contact portion and not including the gate electrode.

12. The device according to claim 11, wherein
the fifth buried electrode part further includes a field plate electrode, and
the gate electrode surrounds a periphery of a portion of the field plate electrode.

13. The device according to claim 11, wherein
the sixth buried electrode part further includes a field plate electrode,
the contact portion surrounds a periphery of a portion of the field plate electrode, and
the field plate electrode contacts the contact portion.

14. The device according to claim 1, wherein
a side surface of the fourth semiconductor region contacted by the contact portion is oblique to a side surface of the first semiconductor region.

15. A method for manufacturing a semiconductor device, the method comprising:
forming a plurality of trenches in a semiconductor layer and forming a mesa part of the semiconductor layer between the plurality of trenches;
forming a gate electrode in the trench, the gate electrode facing a first sidewall of the mesa part;
forming an insulating film that covers the mesa part and the gate electrode;
forming a contact trench by etching the insulating film, the contact trench reaching a second sidewall of the mesa part, the second sidewall being at a side opposite to the first sidewall; and
forming an electrode in the contact trench, the electrode contacting the second sidewall of the mesa part.
